(19) United States
(12) Patent Application Publication
(10) Pub. No.: US 2024/0215279 A1
(43) Pub. Date: Jun. 27, 2024

(54) DISPLAY DEVICE

(71) Applicant: Japan Display Inc., Tokyo (JP)

(72) Inventor: Nobuto MANAGAKI, Tokyo (JP)

(73) Assignee: Japan Display Inc., Tokyo (JP)

(21) Appl. No.: 18/391,722

(22) Filed: Dec. 21, 2023

(30) Foreign Application Priority Data
Dec. 26, 2022 (JP) 2022-208363

(51) Int. Cl. H10K 50/11; H10K 50/16; H10K 50/165

(52) U.S. Cl. CPC H10K 50/11; H10K 50/165; H10K 50/166

(57) ABSTRACT

According to one embodiment, a display device has such configuration that an electron transport layer includes a high-concentration layer and a low-concentration layer, the high-concentration layer is adjacent to an interface with the electron injection layer, the concentration of Liq contained in the high-concentration layer is 70% or more and 90% or less, the concentration of Liq contained in the low-concentration layer is 10% or more and 50% or less, and the thickness of the high-concentration layer is 5% or more and 15% or less of the thickness of the electron transport layer.

### CROSS-REFERENCE TO RELATED APPLICATIONS

This application is based upon and claims the benefit of priority from Japanese Patent Application No. 2022-208363, filed Dec. 26, 2022, the entire contents of which are incorporated herein by reference.

### FIELD

Embodiments described herein relate generally to a display device.

### BACKGROUND

In recent years, display devices which use organic electroluminescent (EL) light emitting materials have been developed. Such display devices include an organic EL layer that contains light emitting materials. In the organic layer of the organic EL element, as electrons and holes recombine each other, the light emitting material is excited, and when the light emitting material returns to its ground state, emission occurs.

### BRIEF DESCRIPTION OF THE DRAWINGS

FIG. 1 is an overall perspective view showing a display device of an embodiment.

FIG. 2 is a partial plan view schematically showing a configuration example of the display device.

FIG. 3 is a cross-sectional view of the display device taken along line A1-A2 shown in FIG. 2.

FIG. 4 is a partially enlarged cross-sectional view illustrating a pixel electrode, an organic EL layer and a common electrode.

FIG. 5 is a diagram showing energy bands of a display device of Comparative Example 1.

FIG. 6 is a diagram showing energy bands of a display device of Comparative Example 2.

FIG. 7 is a diagram showing energy bands of a display device having a staggered structure of the embodiment.

FIG. 8 is a diagram showing energy bands of a display device having a well-like structure of the embodiment.

FIG. 9 is a cross-sectional view of an organic EL layer.

FIG. 10 is a diagram showing a luminance versus time in each of the embodiment and the comparative example.

### DETAILED DESCRIPTION

In general, according to one embodiment, a display device comprises

an anode;

an organic EL layer including a hole injection layer, a hole transport layer, an electron blocking layer, a light emitting layer, a hole blocking layer, an electron transport layer and an electron injection layer; and

a cathode, wherein

the electron transport layer includes a high-concentration layer and a low-concentration layer,

the high-concentration layer is adjacent to an interface with the electron injection layer,

a concentration of Liq contained in the high-concentration layer is 70% or more and 90% or less,

a concentration of Liq contained in the low-concentration layer is 10% or more and 50% or less, and

a thickness of the high-concentration layer is 5% or more and 15% or less of a thickness of the electron transport layer.

An object of this embodiment is to provide a display device with an improved lifetime.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a display device with reference to the drawings.

In this embodiment, a first direction X, a second direction Y and a third direction Z are orthogonal to each other, but may intersect at an angle other than 90 degrees. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

With such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Further, it is assumed that there is an observation position to observe the optical control element on a tip side of the arrow in the third direction Z. Here, viewing from this observation position toward the X-Y plane defined by the first direction X and the second direction Y is referred to as plan view. Viewing a cross-section of the display device in the X-Z plane defined by the first direction X and the third direction Z or in the Y-Z plane defined by the second direction Y and the third direction Z is referred to as cross-sectional view.

### EMBODIMENTS

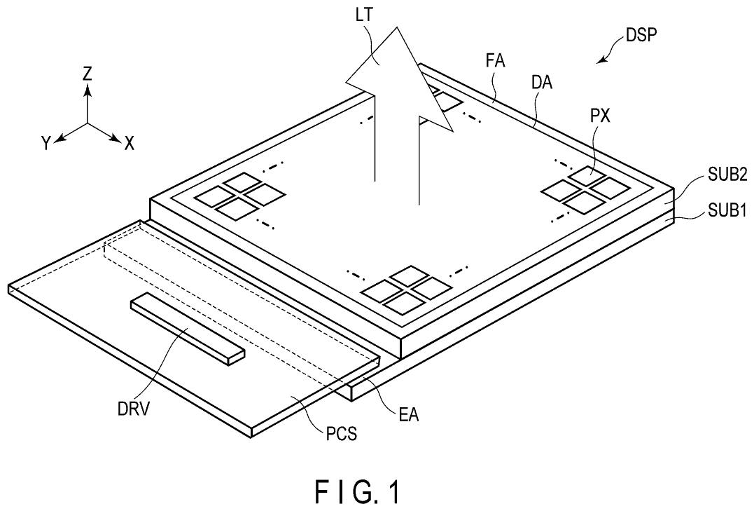

FIG. 1 is an overall perspective view of a display device of an embodiment. A display device DSP comprises a display area DA and a peripheral area FA provided around the display area DA on a substrate SUB1. The display device DSP includes a plurality of pixels PX arranged in the display area DA. In the display device DSP, light LT from the rear surface is transmitted to the front surface and vice versa.

On an upper surface of the display area DA, a substrate SUB2 is provided as a sealing member. The substrate SUB2 is fixed to the substrate SUB1 by a sealing member (not shown) provided to surround the display area DA. The display area DA formed on the substrate SUB1 is sealed so as not to be exposed to the atmosphere by the substrate SUB2 as a sealing member and the sealing material.

An area EA in an end portion of the substrate SUB1 is located outside of the substrate SUB2. In the area EA, a wiring circuit board PCS is provided. On the wiring circuit board PCS, a drive element DRV that outputs video signals and drive signals is provided. Signals from the drive element DRV are input to the pixels PX in the display area DA via the wiring circuit board PCS. Based on the video signals and various control signals, the pixels PX emits light.

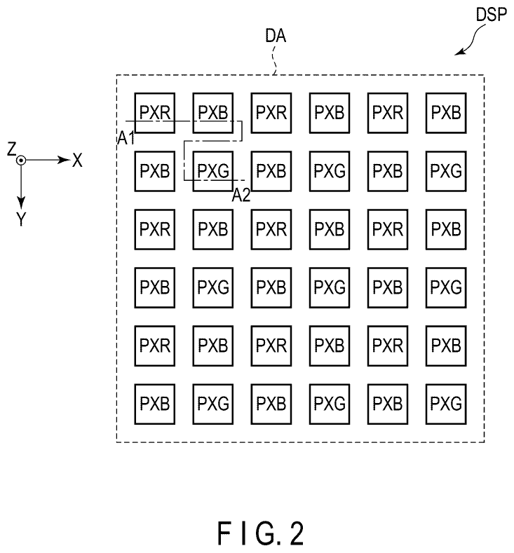

FIG. 2 is a partial plan view schematically showing a configuration example of the display device. The plurality of pixels PX includes pixels PXR which emit red color, pixels PXG which emit green color and pixels PXB which emit blue color. Each pixel PXR is disposed next to respective pixels PXB along the first direction X and the second direction Y. Each pixel PXG is disposed next to respective pixels PXB along the first direction X and the second direction Y. Each pixel PXB is disposed next to a respective pixel PXR along the first direction and next to a respective pixel PXG along the second direction Y.

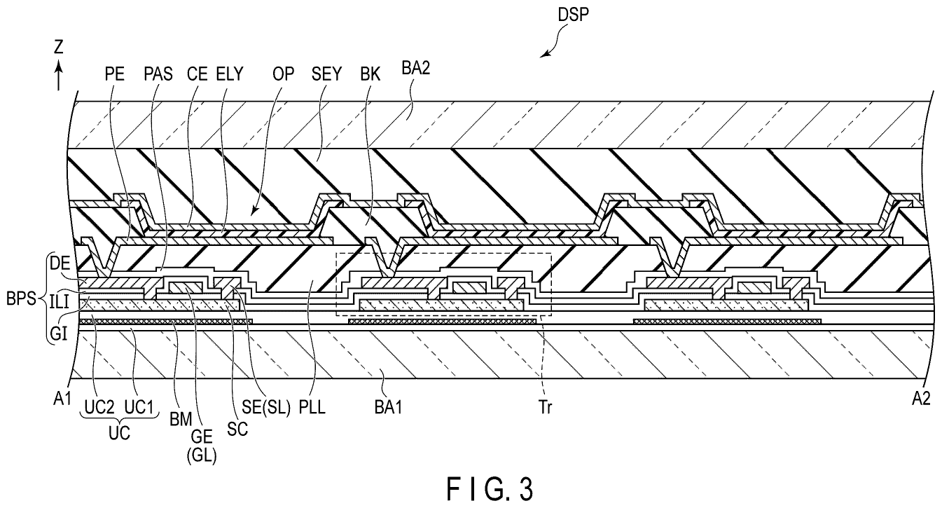

FIG. 3 is a diagram showing a cross-sectional view of the display device taken along line A1-A2 shown in FIG. 2. A base BA1 is, for example, glass or a base material made of a resin material. For example, acrylic, polyimide, polyethylene terephthalate, polyethylene naphthalate or the like may be used as the resin material, and may be formed from a single layer or a stacked body of multiple layers of any of these.

An insulating layer UC1 is provided on the base BA1. The insulating layer UC1 is formed from, for example, a single layer of a silicon oxide film or silicon nitride film or a stacked body of these layers.

On the insulating layer UC1, a light-shielding layer BM may as well be provided to overlap a transistor Tr. The light-shielding layer BM suppresses changes in transistor characteristics, which may be caused by light penetration or the like from the rear surface of the channel of the transistor Tr. When the light-shielding layer BM is formed of a conductive layer, it is also possible to impart a back-gate effect to the transistor Tr by providing a predetermined potential.

An insulating layer UC2 is provided to cover the insulating layer UC1 and the light-shielding layer BM. For the insulating layer UC2, a material similar to that of the insulating layer UC1 can be used. The insulating layer UC2 may as well be made of a material different from that of the insulating layer UC1. For example, silicon oxide can be used for the insulating layer UC1, whereas silicon nitride for the insulating layer UC2. The insulating layers UC1 and UC2 together may be referred to as insulating layer UC.

The transistor Tr is provided on the insulating layer UC. The transistor Tr includes a semiconductor layer SC, an insulating layer GI, a gate electrode GE (a scanning line), an insulating layer ILI, a source electrode SE (a signal line) and a drain electrode DE.

As the semiconductor layer SC, amorphous silicon, polysilicon or an oxide semiconductor is used. As the insulating layer GI, for example, silicon oxide or silicon nitride is provided in a single layer or in a stacked body of these layers.

For example, a molybdenum-tungsten alloy (MoW), a titanium-aluminum alloy (Ti/Al/Ti) or the like is used as the gate electrode GE. The gate electrode GE may be formed to be integrated with the scanning line GL.

The insulating layer ILI is provided to cover the semiconductor layer SC and the gate electrode GE. The insulating layer ILI is formed, for example, by a single layer of a silicon oxide layer or silicon nitride layer or a stacked body of these layers.

On the insulating layer ILI, the source electrode SE and the drain electrode DE are provided. The source electrode SE and drain electrode DE are connected to the source region and drain region of the semiconductor layer SC, respectively, via contact holes made in the insulating layer ILI and the insulating layer GI. The source electrode SE may as well be formed to be integrated with the signal line.

An insulating layer PAS is provided to cover the source electrode SE, the drain electrode DE and the insulating layer ILI. Further, an insulating layer PLL is provided to cover the insulating layer PAS.

The insulating layer PAS is formed using an inorganic insulating material. The inorganic insulating material is, for example, a single layer of silicon oxide or silicon nitride or a stacked body of these. The insulating layer PLL is formed using an organic insulating material. The organic insulating material is, for example, an organic material such as photosensitive acrylic, polyimide or the like. With the insulating layer PLL thus provided, steps caused by the transistor Tr can be planarized.

On the insulating layer PLL, the pixel electrode PE is provided. The pixel electrode PE is connected to the drain electrode DE via contact holes made in the insulating layers PAS and PLL.

The pixel electrode PE is formed from, for example, a three-layer stacked structure of indium zinc oxide (IZO), silver (Ag) and IZO.

In this embodiment, the configuration from the base BA1 to the insulating layer PLL is referred to as a backplane BPS.

A bank BK (which may as well be referred to as a projecting portion or rib) is provided between each adjacent pair of pixel electrodes PE. As the material of the bank BK, an organic material similar to the material of the insulating layer PLL is used. The bank BK is opened to expose a part of the respective pixel electrode PE. Further, it is preferable that an end portion of the opening OP should be gently tapered in cross-sectional view. If the end portion of the opening OP has a steep shape, coverage defects will occur in an organic EL layer ELY that is to be formed later.

The organic EL layer ELY is provided between each adjacent pair of banks BK so as to overlap the respective pixel electrode PE. The organic EL layer ELY includes a hole injection layer HIY, a hole transport layer HTY, an electron blocking layer EBY, a light emitting layer ELL, a hole blocking layer HBY, an electron transport layer ETY and an electron injection layer EIY.

A common electrode CE is provided on the organic EL layer ELY. As the common electrode CE, a magnesium-silver alloy (MgAg) film is formed as a thin film through which the light emitted from the organic EL layer ELY can be transmitted. In this embodiment, the pixel electrode PE serves as an anode and the common electrode CE serves as a cathode. Light emission generated by the organic EL layer ELY is extracted upward via the common electrode CE. In other words, the display device DSP has a top emission structure.

An insulating layer SEY is provided to cover the common electrode CE. The insulating layer SEY has a function of preventing moisture from entering the organic EL layer ELY from the outside. As the insulating layer SEY, a material having a high gas barrier property is preferable. As the insulating layer SEY, for example, a layer obtained by sandwiching an organic insulating layer between two inorganic insulating layers containing nitrogen, can be used. Examples of the material for the organic insulating layer are acrylic resin, epoxy resin and polyimide resin. Examples of the material for the inorganic insulating layer containing nitrogen are silicon nitride and aluminum nitride.

A base BA2 is provided on the insulating layer SEY. The base BA2 is formed of a material similar to that of the base BA1. Between the base BA2 and the insulating layer SEY, a translucent inorganic insulating layer or a translucent organic insulating layer may as well be provided. The organic insulating layer may as well have the function of adhering the insulating layer SEY and the base BA2 together.

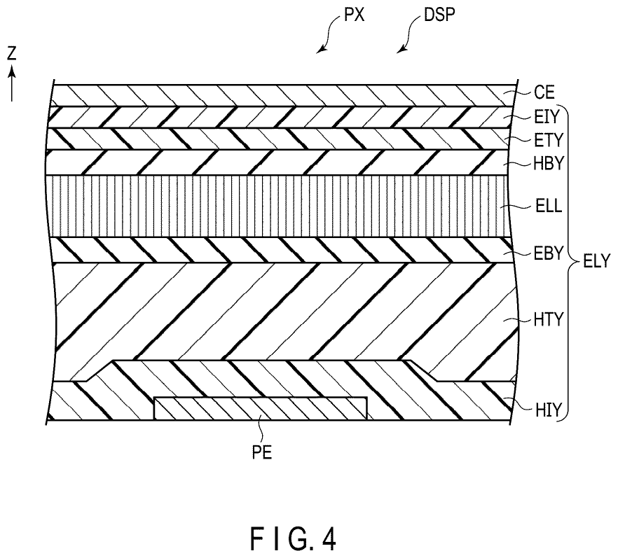

FIG. 4 is a partially enlarged cross-sectional view illustrating the pixel electrode, the organic EL layer and the common electrode. In FIG. 4, the components from the pixel electrode PE to the common electrode CE in each pixel PX are shown. However, the illustration of the bank BK is omitted.

The pixels PX each includes a hole injection layer HIY, a hole transport layer HTY, an electron blocking layer EBY, a light emitting layer ELr (ELL), a hole blocking layer HBY, an electron transport layer ETY, an electron injection layer EIY and a common electrode CE on the pixel electrode PE.

Light emission in the organic EL layer ELY is obtained when the light is emitted as the excitation energy of excitons generated by holes injected into the highest occupied molecular orbital (HOMO, generally measured as ionization potential) and electrons injected into the lowest unoccupied molecular orbital (LUMO, generally measured as electron affinity) of the material of the light emitting layer ELL is relaxed.

The hole injection layer HIY, the hole transport layer HTY, the electron blocking layer EBY, the hole blocking layer HBY, the electron transport layer ETY, the electron injection layer EIY and the common electrode CE are provided over the entire surfaces of the plurality of pixels PX. They are formed as so-called solid films.

The material for the hole injection layer HIY is a material having a high efficiency of hole injection from the anode (the pixel electrode PE). The hole transport layer HTY transports the injected holes to the light emitting layer ELL. The electron blocking layer EBY keeps the electrons injected from the cathode (the common electrode CE) in the light emitting layer ELL and prevents them from leaking to the hole transport layer HTY.

The electron injection layer EIY injects electrons from the cathode, and the electron transport layer ETY transports the injected electrons to the light emitting layer ELL. The hole blocking layer HBY keeps the holes injected from the anode in the light emitting layer ELL and prevents them from leaking out to the electron transport layer ETY.

In the pixels PX of this embodiment, the light from the light-emitting layer ELL is emitted upward or downward. The light emitted upward is extracted to the outside via the common electrode CE. Note that the light emitted downward may be reflected by a reflective layer provided on the pixel electrode PE. On the common electrode CE as well, a reflective layer may be provided and the light reflected thereby may be reflected between each of the pixel electrodes PE and the common electrode CE. With this configuration, of the light emitted by the light-emitting layer ELL, only the light having a resonance wavelength is amplified. As a result, light having high peak intensity and a spectrum of narrow width can be extracted, which makes it possible to expand the color reproduction range of the display device DSP (the microcavity effect).

Further, as to the hole injection layer HIY and the hole transport layer HTY, by lowering the hole injection barrier (the difference between the work function of the anode and the HOMO level of the material of the hole transport layer HTY) from the pixel electrode PE (the anode), holes can be allowed to flow smoothly.

As to the electron injection layer EIY or the electron transport layer ETY, electrons can be allowed to flow smoothly by lowering the electron injection barrier (the difference between the work function of the cathode and the LUMO level of the material of the adjacent electron transport layer ETY) from the common electrode CE (the cathode).

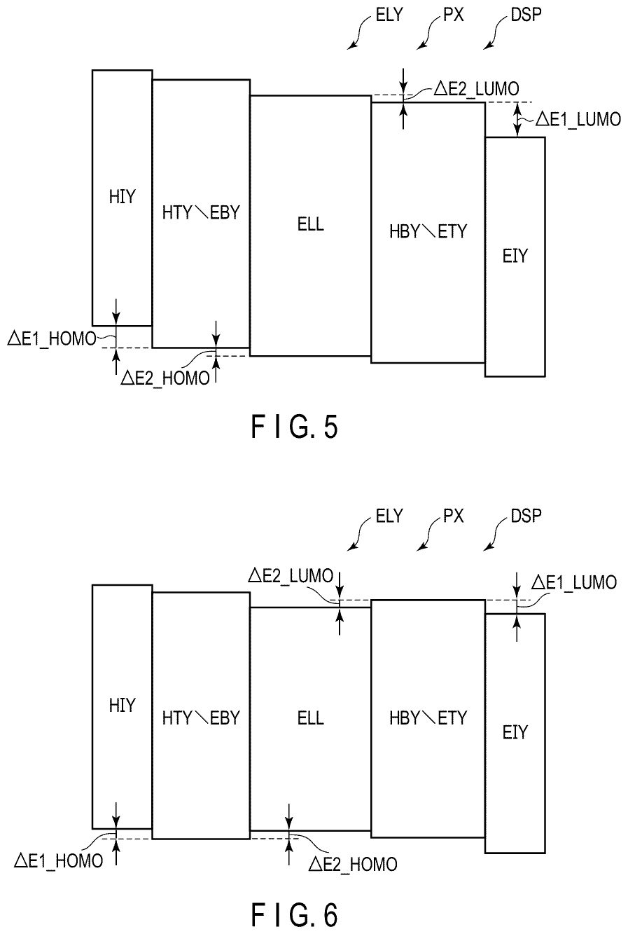

FIG. 5 is a diagram showing the energy bands of a display device of Comparative Example 1. When the hole transport layer HTY is provided between the pixel electrodes PE (the anode) and the light emitting layer ELL, in order to make hole injection and hole transport from the pixel electrode PE more effective, the hole injection material and hole transport material are selected so that a staircase-shaped potential barrier is created in the interface of each layer from the Fermi level of the pixel electrode PE to the HOMO level of the light emitting layer ELL. Such a staircase-shaped potential barrier is referred to as a staggered configuration.

Similarly, when the electron transport layer ETY is provided between the common electrode CE (the cathode) and the light emitting layer ELL, in order to make electron injection and transport from the common electrode CE to be carried out more effective, the electron injection material and transport material are selected so that a staircase-like potential barrier is created in the interface of each layer from the Fermi level of the common electrode CE to the LUMO level of the light emitting layer ELL. With the staircase-shaped potential barrier thus provided, it is possible to improve the properties of the carrier injection to the light emitting layer ELL and enhances the light emission performance.

The potential barrier between the electron injection layer EIY, and the electron transport layer ETY and the hole blocking layer HBY is referred to as ΔE1_LUMO. The potential barrier between the electron transport layer ETY and the hole blocking layer HBY, and the light emitting layer ELL is referred to as ΔE2_LUMO.

By making ΔE1_HOMO and ΔE2_HOMO, which are the hole transport pathways and ΔE1_LUMO and ΔE2_LUMO, which are the electron transport pathways, as small as possible, carriers are allowed to flow smoothly and the voltage (V)-current(I) characteristics (which may as well be referred to as VI characteristics) of the pixel PX can be improved.

FIG. 6 is a diagram showing the energy bands of a display device of Comparative Example 2. In FIG. 6, the HOMO level of the light-emitting layer ELL and the HOMO levels of the adjacent carrier transport layers (a hole transport layer HTY and an electron transport layer ETY) are compared, and the HOMO levels of the carrier transport layers are lower. Also, the LUMO level of the light-emitting layer ELL and the LUMO levels of the adjacent carrier transport layers (a hole transport layer HTY and an electron transport layer ETY) are compared, and the LUMO levels of the carrier transport layers are higher. The potential barriers shown in FIG. 6 is referred to as a well-like structure.

In FIG. 6 as well, the hole transport pathways are ΔE1_HOMO and ΔE2_HOMO, and the electron transport pathways are ΔE1_LUMO and ΔE2_LUMO. ΔE1_HOMO indicates the energy difference in HOMO between materials adjacent to each other. As an example here, the HOMO energy difference between the hole injection layer HIY and the hole transport layer HTY is shown. Similarly, ΔE2_HOMO indicates the energy difference in HOMO between the electron blocking layer EBY and the light emitting layer ELL. ΔE1_LUMO indicates the energy difference in LUMO between materials adjacent to each other. As an example here, the LUMO energy difference between the electron injection layer EIY and the electron transport layer ETY is shown. Similarly, ΔE2_LUMO indicates the energy difference in LUMO between the hole blocking layer HBY and the light emitting layer ELL.

As described above, in order for the current to flow smoothly, it is preferable that ΔE1_HOMO, ΔE2_HOMO, ΔE1_LUMO and ΔE2_LUMO should be as small as possible.

However, when ΔE2_HOMO and ΔE2_LUMO are excessively small, the V-I characteristics of the organic EL layer ELY may undesirably deteriorate. Note here that the recombination of electrons and holes in the light-emitting layer ELL occurs proportional to the square of the carriers. Therefore, if the light-emitting layer ELL no longer functions as a barrier layer, the confinement of carriers is weakened, which is considered to be a factor of the deterioration of the characteristics. In other words, the advantage that carriers can easily flow into the light emitting layer ELL is as well the disadvantage that carriers can easily flow out of the light emitting layer ELL.

Under these circumstances, in this embodiment, the light-emitting layer ELL is made wide-gap so as to confine the carriers. In this manner, it is possible to make it difficult for carriers to flow out of the light-emitting layer ELL, thereby improving the light emission lifetime of the organic ELY layer.

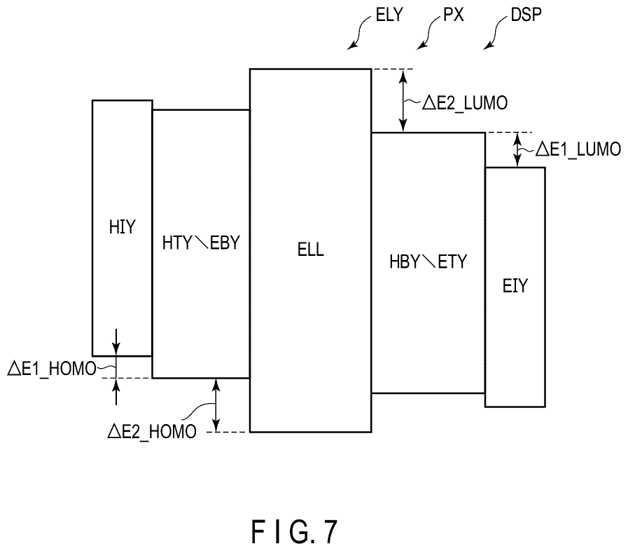

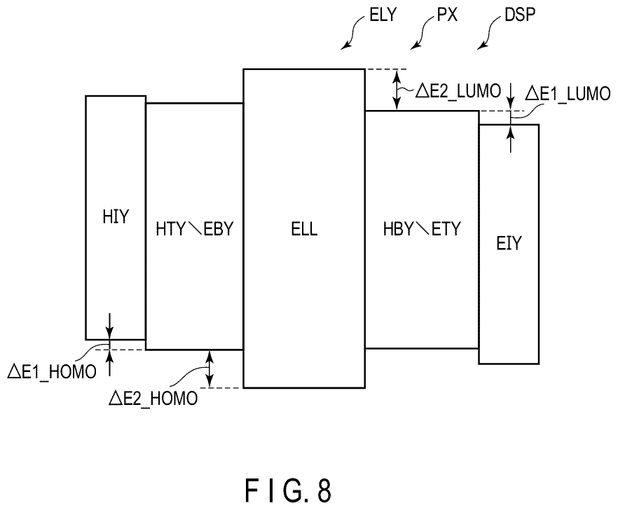

FIG. 7 is a diagram showing the energy bands of a display device having the staggered structure of this embodiment. FIG. 8 is a diagram showing the energy bands of a display device having a well-like structure of this embodiment.

In FIGS. 7 and 8, the HOMO level of the light emitting layer ELL is lower than the HOMO level of the adjacent carrier transport layers (a hole transport layer HTY and an electron blocking layer EBY, and an electron transport layer ETY and a hole blocking layer HBY). The LUMO level of the light emitting layer ELL is higher than the LUMO level of the adjacent carrier transport layers (a hole transport layer HTY and an electron transport layer ETY).

ΔE2_LUMO, which is the potential barrier between the electron transport layer ETY and the hole blocking layer HBY, and the light emitting layer ELL, and ΔE2_HOMO, which is the potential barrier between the hole transport layer HTY and the electron blocking layer EBY, and the light emitting layer ELL, will be referred to as ΔE2 when they are not particularly distinguished from each other. It is preferable that ΔE2 should be 0.1 eV or higher and 0.5 eV or lower (0.1 eV≤ΔE2≤0.5 eV). If ΔE2 is smaller than 0.1 eV (ΔE2<0.1 eV), carriers flow easily as described with reference to FIGS. 5 and 6. This results in a longer light emission lifetime of excitons and lower efficiency.

In order to make ΔE2 within the above-specified range, it suffices if a material that can make the light emitting layer ELL wide-gap (hereinafter referred to as “wide-gap material”) is co-deposited when depositing the light emitting layer ELL. In addition, to make ΔE2 fall within the above-specified range, for example, appropriate materials should be selected and the film thickness should be made appropriate.

ΔE1_LUMO, which is the potential barrier between the electron injection layer EIY, and the electron transport layer ETY and the hole blocking layer HBY, and ΔE1_HOMO, which is the potential barrier between the hole injection layer HIY, and the hole transport layer HTY and the electron blocking layer EBY, will be referred to as ΔE1 when they are not specifically distinguished from each other. ΔE1 should be 0.5 eV or less (ΔE1≤0.5 eV). Further, ΔE1 should be 0.35 eV or less (ΔE1≤0.35 eV). Furthermore, when ΔE1_LUMO≤0.2 eV, the best configuration can be obtained. ΔE1_LUMO is assumed based on that a work function of the common electrode CE in contact with the electron injection layer EIY is 3.5 eV.

The film thickness for confinement of carriers is affected by the lower one of the mobility of holes and that of electrons. Let us consider now, for example, the case where the mobility of electrons is lower than that of holes. When the mobility of electrons is 1×10⁻⁶ cm²/Vs, it is preferable that the film thickness should be 30 nm or more and 40 nm or less. When the mobility of electrons is 1×10⁻¹⁰ cm²/Vs, it is preferable that the film thickness should be 20 nm or more and 30 nm or less.

Here, let us now consider degradation in lifetime of the display device DSP of this embodiment. The carrier balance of electrons and holes in the organic EL layer ELY may undesirably cause a factor of the decrease in lifetime of the display device DSP.

The electron transport layer ETY of this embodiment (see FIG. 4) is deposited by the co-evaporation method. The material of the electron transport layer ETY contains an n-type carrier injection material. As the n-type carrier injection material, for example, (8-hydroxyquinolinolato)lithium (Liq) can be used. Further, the hole injection layer HIY of this embodiment (see FIG. 4) is deposited by the co-evaporation method. The material of the hole injection layer HIY contains a p-type dopant. As the p-type dopant, for example, 2-(7-dicyanomethylene-1,3,4,5,6,8,9,10-octafluoro-7H-pyrene-2-ylidene)-malononitrile (NPD-9) can be used. The concentration of the p-type dopant should preferably be 1.0% to 1.5%.

In the formation of the electron transport layer ETY, the amount of electron supply is determined by the Liq concentration with regard to the concentration of the p-type dopant. When the Liq concentration is increased to increase the amount of electron supply, the ΔE1_LUMO between Liq, which functions as well as the electron injection layer EIY, and the electron transport layer ETY increases (see FIGS. 7 and 8). As a result of this, the amount of electron supply is saturated or decreased. Further, the risk of decreasing the lifetime of the display device DSP may be created.

In this embodiment, the electron transport layer ETY of the organic EL layer ELY is improved so as to make it possible to enhance the lifetime of the display device DSP.

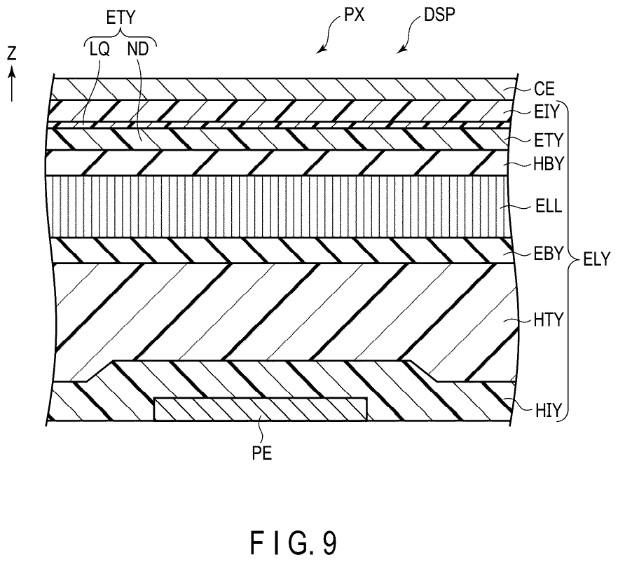

FIG. 9 is a cross-sectional view illustrating the organic EL layer. In the example shown in FIG. 9, a layer containing a high concentration of Liq is formed in the vicinity of the boundary of the electron injection layer EIY in the electron transport layer ETY. In the electron transport layer ETY, the high-concentration layer is referred to as LQ, and the layer containing low concentration Liq other than the high concentration layer LQ is referred to as low-concentration layer ND.

In the example shown in FIG. 9, the thickness of the electron transport layer ETY is 22.6 nm. The low concentration layer ND of the electron transport layer ETY contains Liq at a concentration of 10% or higher and 50% or lower, more specifically, at 20%.

The high concentration layer LQ contains Liq at a concentration of 70% or higher and 90% or lower, more specifically, at 80%. The thickness of the high concentration layer LQ is 1 nm or greater and 3 nm or less, more specifically, 2.6 nm. The light emitting layer ELL is a light emitting layer that emits blue light. The thickness of the high concentration layer LQ is 5% or more and 15% or less of the thickness of the entire electron transport layer ETY.

In order to form the low concentration layer ND and the high concentration layer LQ by the co-evaporation method, for example, a plurality of chambers may be prepared and a deposition source for co-evaporation may be installed in each chamber. Here, by controlling the opening and closing of the chambers, two layers with different concentrations can be deposited.

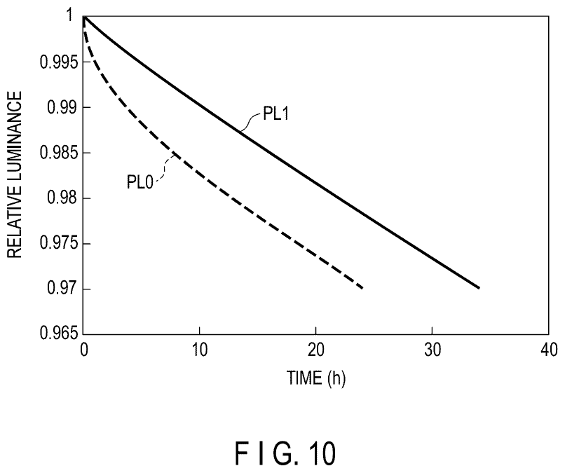

FIG. 10 is a diagram showing the luminance versus time in each of the configurations of the embodiment and a comparative example. The electron transport layer ETY of the embodiment includes a high-concentration layer LQ at the boundary of the electron injection layer EIY, as described above. In the electron transport layer of the comparative example, a high-concentration layer is not formed at the boundary of the electron injection layer EIY.

In FIG. 10, a plot PL1 of the embodiment is represented by a solid line and the plot PL0 of the comparative example is represented by a dotted line. The lateral axis in FIG. 10 indicates the time (TIME) (h) from the start of light emission, and the vertical axis indicates the relative luminance (RELATIVE LUMINANCE).

As shown in FIG. 10, the plot PL0 of the comparative example has a steeper decrease in luminance versus time as compared to that of the plot PL1 of the embodiment. In other words, the configuration of the embodiment, in which the high concentration layer LQ is formed, has a longer lifetime than that of the comparative example. Thus, the display device DSP of this embodiment exhibits the effect of improving the lifetime.

Liq molecules are stronger and more solid than other co-deposition molecules. Therefore, with the high-concentration layer LQ thus provided, the interface of the electron transport layer ETY becomes stronger. As a result, it is considered that the display device DSP of this embodiment can improve the life time.

In this display device, as to the chromaticity of blue, CIEx=0.141 and CIEy=0.05, and CIEy plays an important role in designing of the pixels.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
an anode;
an organic EL layer including a hole injection layer, a hole transport layer, an electron blocking layer, a light emitting layer, a hole blocking layer, an electron transport layer and an electron injection layer; and
a cathode, wherein
the electron transport layer includes a high-concentration layer and a low-concentration layer,
the high-concentration layer is adjacent to an interface with the electron injection layer,
a concentration of Liq contained in the high-concentration layer is 70% or more and 90% or less,
a concentration of Liq contained in the low-concentration layer is 10% or more and 50% or less, and
a thickness of the high-concentration layer is 5% or more and 15% or less of a thickness of the electron transport layer.

2. The display device according to claim 1, wherein
a thickness of the electron transport layer is 22.6 nm, and
a thickness of the high-concentration layer is 2.6 nm.

3. The display device according to claim 1, wherein the concentration of Liq contained in the high-concentration layer is 80%.

4. The display device according to claim 1, wherein
the concentration of Liq contained in the low-concentration layer is 20%.

5. The display device according to claim 1, wherein
the light emitting layer emits blue light.

6. The display device according to claim 1, wherein
when a difference in LUMO energy of the electron injection layer and the electron transport layer is defined as ΔE1_LUMO, the ΔE1_LUMO is 0.2 eV or less.
